(19) United States
(12) Patent Application Publication
(10) Pub. No.: US 2003/0075788 A1
(43) Pub. Date: Apr. 24, 2003

(54) Stacked semiconductor package and fabricating method thereof

(76) Inventor: Un-Young Chung, KwangJu-si (KR)

Correspondence Address: McGuireWoods, Suite 1800, 1750 Tysons Boulevard, McLean, VA, 22102-4215, US

(21) Appl. No.: 10/175,827

(22) Filed: Jun. 21, 2002

(30) Foreign Application Priority Data
Oct. 24, 2001 (KR) 2001-65683

(51) Int. Cl. H01L 21/44; H01L 23/02

(52) U.S. Cl. 257/678; 438/109; 438/118; 438/107; 438/455; 257/686; 257/690

(57) ABSTRACT

The present invention relates to a stacked semiconductor package and a fabricating method thereof, wherein patterned conductor portions having a wiring function for changing the wiring of leads for controlling operations of stacked semiconductor chips are printed on surfaces of the semiconductor chips. According to the present invention, when the semiconductor chips are stacked one above another, the fabrication processes are simplified by eliminating use of a printed circuit board (PCB) with wiring formed therein for connecting the leads of the semiconductor chips to each other. Further, the connection between the leads can be made in various manners by using an electrically conductive ink or adhesive, so that the stacked semiconductor package can be easily fabricated.

### BACKGROUND OF THE INVENTION

1. Field of the Invention

The present invention relates to a stacked package of semiconductor chips, and more specifically, to a stacked semiconductor package and a fabricating method thereof, wherein patterned conductor portions having a wiring function for changing the wiring of leads for controlling operations of stacked semiconductor chips are printed on surfaces of the semiconductor chips.

2. Description of the Prior Art

As a method of achieving high integration of a semiconductor chip, there has been generally known a technique for integrating much more cells into a limited space of a semiconductor device. However, such a method requires high-level technology and much development time such as a need for a fine line-width with high precision. As a result, many studies have been conducted on so-called stack packaging technology by which the high integration of the semiconductor chip can be achieved in a simple manner. In the stack packaging technology, a memory capacity is doubled by vertically stacking two or more semiconductor chips one above another, for example, an 128M DRAM device can be constructed by stacking two 64M DRAM devices one above another.

U.S. Pat. No. 6,242,285 claiming priorities based on Korean Patent Application Nos. 1998-29723 (Jul. 23, 1998), 1998-36556 (Sep. 4, 1998), 1998-37974 (Sep. 15, 1998), 1998-38739 (Sep. 18, 1998) and 1998-44335 (Oct. 22, 1998) discloses a stacked package of semiconductor chips in which chip-selection (/CS) leads of upper and lower semiconductor chips 10 and 20 are connected through a printed circuit board (PCB) (14), as shown in FIGS. 1a and 1b. The chip-selection (/CS) lead allows selection of an operation of the semiconductor chip. The semiconductor chip operates only when an operation signal is applied to the chip-selection (/CS) lead. In a case where the semiconductor chips are stacked one above another, a chip-selection (/CS) lead of one semiconductor chip is connected to one of leads except for a chip-selection (/CS) lead of another semiconductor chip.

However, since such a stacked package has the PCB interposed between the two semiconductor chips, the volume of the package becomes bulky, which is disadvantageous to miniaturization of the semiconductor package. Further, since a process of forming the wiring for lead connection on the PCB is very complicated, there are disadvantages in that fabrication costs thereof is increased and fabrication processes are complicated.

### SUMMARY OF THE INVENTION

The present invention is conceived to solve the problems in the prior art. An object of the present invention is to enable fabrication of a compact semiconductor package by bringing semiconductor chips directly into contact with each other without using a PCB.

Another object of the present invention is to enable simplification of fabricating processes and great saving on fabrication costs by eliminating use of a separate means with wiring formed therein when connection between leads of the semiconductor chips is changed.

According to the present invention for achieving the objects, patterned conductor portions are printed on a top or bottom surface of the semiconductor chip.

The patterned conductor portion may be formed on the bottom surface of a first semiconductor chip or the top surface of a second semiconductor chip. If necessary, the patterned conductor portions may be formed on both facing surfaces of the semiconductor chips to be stacked.

When the two semiconductor chips are bonded after the patterned conductor portions are printed on the surfaces thereof, a soldering method which has generally been used in a conventional fabrication method of a stacked semiconductor package may be employed for connection of the leads of the semiconductor chips. Alternatively, the leads may be connected to each other by applying an electrically conductive adhesive to the leads and then bonding them, or by performing fusion welding at high temperature such as an electric welding to bond the leads.

### BRIEF DESCRIPTION OF THE DRAWINGS

The above and other objects and features of the present invention will become apparent from the following description of preferred embodiments given in conjunction with the accompanying drawings, in which:

FIGS. 1a and 1b are a perspective view and a side view of a stacked semiconductor package according to the prior art, respectively;

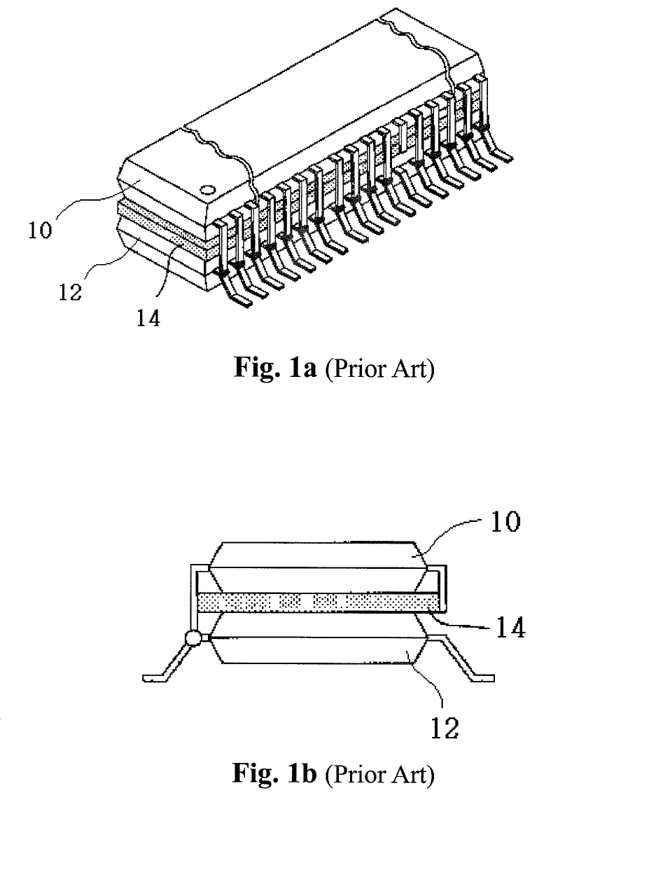

FIG. 2a is a perspective view of a stacked semiconductor package, which is formed by stacking two semiconductor chips one above another, according to one embodiment of the present invention, and FIG. 2b is a sectional view showing a stacked structure of the bonded semiconductor chips, taken along line A-A of FIG. 2a; and

FIG. 3a is a perspective view of a stacked semiconductor package, which is formed by stacking two semiconductor chips one above another, according to another embodiment of the present invention, and FIG. 3b is a sectional view showing a stacked structure of the bonded semiconductor chips, taken along line B-B of FIG. 3a.

### DETAILED DESCRIPTION OF THE PREFERRED EMBODIMENTS

Hereinafter, preferred embodiments of the present invention will be described in detail with reference to the accompanying drawings.

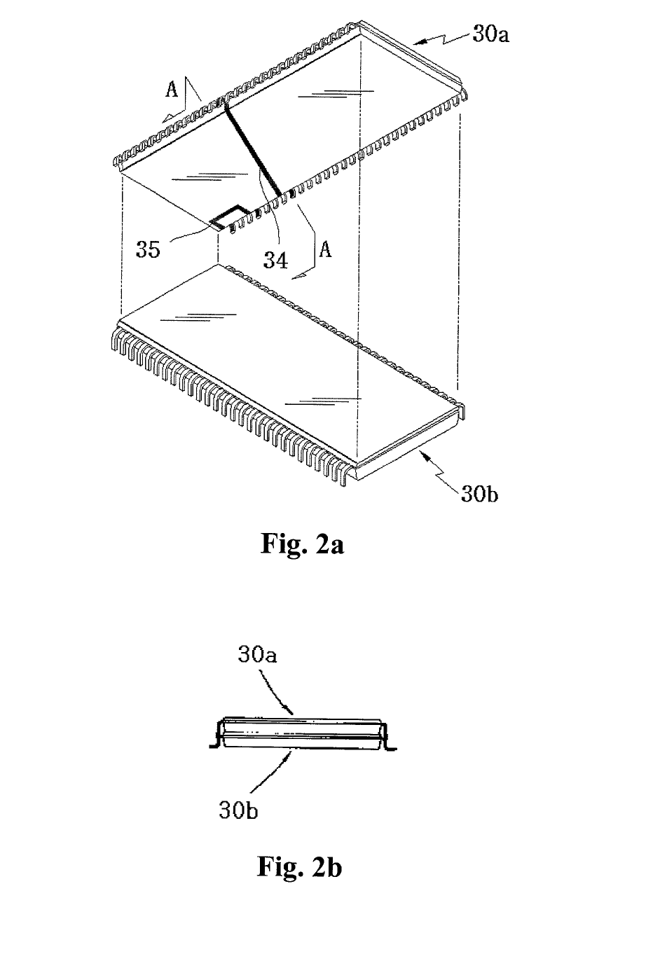

FIG. 2a is a perspective view of a stacked semiconductor package, which is formed by stacking two semiconductor chips one above another, according to one embodiment of the present invention. FIG. 2b is a sectional view showing a stacked structure of the bonded semiconductor chips, taken along line A-A of FIG. 2a. As shown in the figures, the semiconductor package is formed by vertically stacking upper and lower semiconductor chips 30a and 30b one above another. Patterned conductor portions 34, 35 are printed on a bottom surface of the upper semiconductor chip 30a so that they electrically connect specific leads to each other. Such patterned conductor portions can be formed in various configurations so as to change lead functions in accordance with functions of the semiconductor chips.

As shown in FIG. 2b, after the upper semiconductor chip 30a is stacked on the lower semiconductor chip 30b, the two semiconductor chips are bonded to each other. In order to connect the leads of the semiconductor chips, a soldering method which has generally been used in a conventional fabrication method of a stacked semiconductor package may be employed. Alternatively, the leads may be connected to each other by applying an electrically conductive adhesive to the leads and then bonding them, or by performing fusion welding at high temperature such as an electric welding to bond the leads.

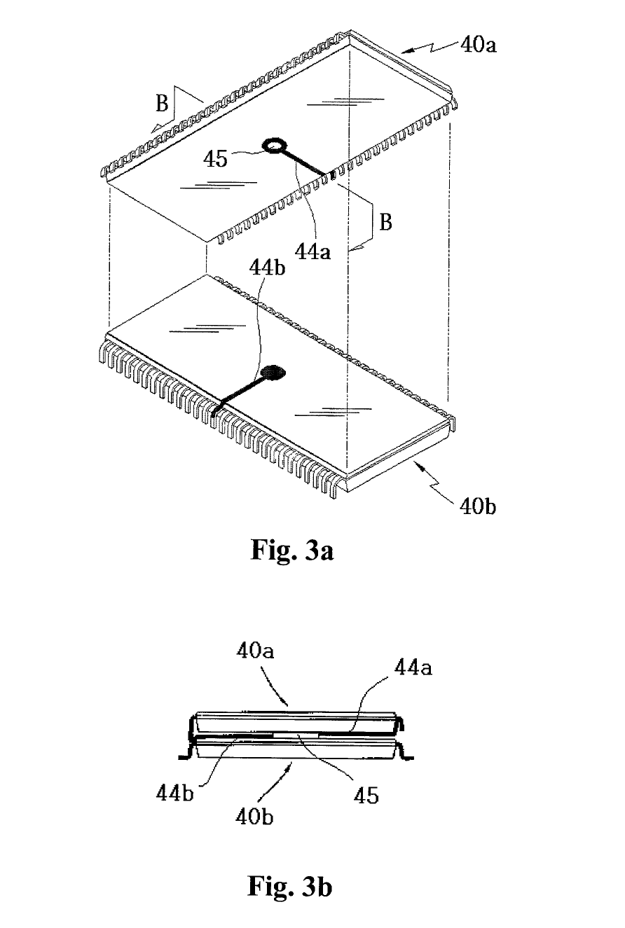

FIG. 3a is a perspective view of a stacked semiconductor package, which is formed by stacking two semiconductor chips one above another, according to another embodiment of the present invention. FIG. 3b is a sectional view showing a stacked structure of the bonded semiconductor chips, taken along line B-B of FIG. 3a. There is shown an example in which patterned conductor portions 44a, 44b are formed on a bottom surface of an upper semiconductor chip 40a and a top surface of a lower semiconductor chip 40b, respectively.

The patterned conductor portion 44a is printed on the surface of the upper semiconductor chip 40a in a state where it is connected to any one of the leads of the right lead group of the upper semiconductor chip 40a. The patterned conductor portion 44b is printed on the surface of the lower semiconductor chip 40b in a state where it is connected to any one of the leads of the left lead group of the lower semiconductor chip 40b. When the two semiconductor chips are stacked one above another, the respective patterned conductor portions abut against the relevant conductor portions. As a result, the respective leads that have been connected to the patterned conductor portions are electrically connected to the relevant leads. Particularly, the patterned conductor portion 44a formed on the surface of the upper semiconductor chip 40a has a space 45 therein. The electrically conductive adhesive is applied to the space 45 to facilitate the bonding of the abutted surfaces of the semiconductor chips when the upper semiconductor chip is stacked on the lower semiconductor chip.

Referring to FIG. 3b, for clarity of explanation, the patterned conductor portions 44a, 44b that have been formed on the respective surfaces of the semiconductor chips are shown in a somewhat exaggerated manner between the bottom surface of the upper semiconductor chip 40a and the top surface of the lower semiconductor chip 40b. Although there is shown a gap between the two semiconductor chips in the figure, the semiconductor chips are completely brought into contact with each other without any gap therebetween in practice. Such patterned conductor portions can be formed in various configurations so as to change lead functions in accordance with functions of the semiconductor chips.

According to the present invention, the patterned conductor portions can be made of an electrically conductive ink or adhesive to electrically connect a specific lead of the upper semiconductor chip to a specific and relevant lead of the lower semiconductor chip.

Chip-selection (/CS) leads for enabling the respective semiconductor chips to be selected in response to external signals should be disposed at different positions in order to operate each of the semiconductor chips of the stacked semiconductor package. The chip-selection (/CS) leads of the respective semiconductor chips can be selected independently of each other by the patterned conductor portions.

The electrically conductive ink is prepared, for example, by mixing electrically conductive materials with an organic solvent. Gold or silver can be used as the electrically conductive materials. Alternatively, the electrically conductive materials may include any electrically conductive materials such as copper, aluminum, and other materials that can form printed patterns.

Meanwhile, the patterned conductor portions to be formed on the top and bottom surfaces of the semiconductor chips can be formed directly on the surfaces themselves of the semiconductor chips. Alternatively, etched portions may be first formed on the surfaces of the semiconductor chips in the same configuration as patterns to be formed on the surfaces and then filled with the electrically conductive ink or adhesive. In such a case, the patterned conductor portions do not have a certain height on the surfaces of the semiconductor chips but are flush with the surfaces of the semiconductor chips.

The patterned conductor portions can be printed by silk screen printing. However, they may also be printed by other printing methods.

After the patterned conductor portions are formed on the surfaces of the semiconductor chips, the leads of the lower semiconductor chip are electrically connected to the leads of the upper semiconductor chip. In a stacking process performed in fabrication of the semiconductor package, how the stacked devices are electrically connected is important. Soldering is one of most commonly used methods employed in such vertical connection. However, the soldering is carried out after applying flux to the leads so as to connect the leads to each other, and then a cleaning process should be performed to remove the flux. Accordingly, since such troublesome and complicated processes should be performed, the productivity is lowered. Therefore, the present invention proposes another method of connecting the leads.

First, the leads of the lower semiconductor chip can be electrically connected to the leads of the upper semiconductor chip by using the electrically conductive adhesive. The electrically conductive adhesive is prepared by mixing electrically conductive materials with a general adhesive. For example, silver powder can be mixed with the general adhesive to prepare the electrically conductive adhesive.

As a further method of connecting the leads, the leads of the lower semiconductor chip can be electrically connected to the leads of the upper semiconductor chip by using fusion welding. When heat is applied to the leads, the leads of the upper and lower semiconductor chips can be bonded to each other due to a lead (Pb) component remaining in the leads. The heat can be applied in various manners. Preferably, electric welding is used since the leads are small in size and the distance between the leads is short.

In such a way, if the respective leads are connected to each other by using the electrically conductive adhesive and the fusion welding instead of the soldering that has been commonly used for the connection of the leads, the soldering process can be eliminated. Consequently, the fabrication processes can be simplified and the fabrication costs can be greatly reduced.

In order to further facilitate the stacking of the two semiconductor chips in addition to the connection of the leads, it is preferred that the bonding state of the upper and lower semiconductor chips be reinforced by applying the adhesive therebetween.

As an embodiment of the application of the adhesive, the upper and lower semiconductor chips can be bonded to each other by applying the electrically conductive adhesive around the patterned conductor portions on the surfaces of the semiconductor chips. In this case, it is necessary to prevent undesired electrical connection made between the leads due to adhesion of the adhesive to the leads of the semiconductor chips.

Therefore, in the case where the adhesive is used for reinforcing the bonding of the semiconductor chips, it is also preferred that the upper and lower semiconductor chips be bonded to each other by applying both the electrically conductive adhesive and an insulation adhesive instead of application of only the electrically conductive adhesive.

With the methods of stacking the semiconductor chips according to the present invention described above, it is possible to stack two semiconductor chips as well as three or more semiconductor chips.

According to the present invention, the semiconductor chips are stacked one above another in the direct contact manner, so that a more compact semiconductor package can be fabricated. Further, since a separate PCB with wiring formed therein is not required for changing the connection of the leads of the semiconductor chips, there are advantages in that the fabrication processes can be simplified and the fabrication costs can be greatly reduced.

Although the present invention has been described in connection with the various embodiments, the present invention is not limited thereto. It is understood by those skilled in the art that various modifications and changes to the present invention may be made without departing from the spirit and scope of the invention, and these modifications and changes also fall within the scope of the present invention.

What is claimed is:

1. An improved, stacked semiconductor package including at least two semiconductor chips stacked one above another, the improvement comprising:
patterned conductor portions printed on either of facing surfaces of first and second semiconductor chips to be stacked,
wherein the patterned conductor portions extend from a predetermined lead of the first semiconductor chip to another predetermined lead of the first semiconductor chip or from a predetermined lead of the second semiconductor chip to another predetermined lead of the second semiconductor chip, said predetermined leads of each semiconductor chip being required to be electrically connected to each other.

2. The improved, stacked semiconductor package as claimed in claim 1, wherein the patterned conductor portions are printed by using an electrically conductive ink or adhesive.

3. The improved, stacked semiconductor package as claimed in claim 1, wherein after the first and second semiconductor chips are stacked one above another, the leads of the first and second semiconductor chips are bonded to each other by an electrically conductive adhesive or fusion welding.

4. The improved, stacked semiconductor package as claimed in claim 1, wherein the patterned conductor portions are constructed by forming etched portions on either of the surfaces of the semiconductor chips and then filling the etched portions with an electrically conductive ink or adhesive.

5. The improved, stacked semiconductor package as claimed in claim 2, wherein the patterned conductor portions are constructed by forming etched portions on either of the surfaces of the semiconductor chips and then filling the etched portions with an electrically conductive ink or adhesive.

6. An improved, stacked semiconductor package including at least two semiconductor chips stacked one above another, the improvement comprising:
first patterned conductor portions extending from a predetermined lead of a first semiconductor chip to a region on a surface of the first semiconductor chip; and
second patterned conductor portions extending from a predetermined lead of a second semiconductor chip to a region on a surface of the second semiconductor chip,
wherein the first and second semiconductor chips are stacked one above another so that the first patterned conductor portions are electrically connected to the second patterned conductor portions.

7. The improved, stacked semiconductor package as claimed in claim 6, wherein the first and second patterned conductor portions are printed by using an electrically conductive ink or adhesive.

8. The improved, stacked semiconductor package as claimed in claim 6, wherein after the first and second semiconductor chips are stacked one above another, the leads of the first and second semiconductor chips are bonded to each other by an electrically conductive adhesive or fusion welding.

9. The improved, stacked semiconductor package as claimed in claim 6, wherein the first and second patterned conductor portions are constructed by forming etched portions on the surfaces of the semiconductor chips and then filling the etched portions with an electrically conductive ink or adhesive.

10. The improved, stacked semiconductor package as claimed in claim 7, wherein the first and second patterned conductor portions are constructed by forming etched portions on the surfaces of the semiconductor chips and then filling the etched portions with an electrically conductive ink or adhesive.

11. The improved, stacked semiconductor package as claimed in claim 6, wherein either of the patterned first and second conductor portions has a space to which an adhesive is applied.

12. The improved, stacked semiconductor package as claimed in claim 7, wherein either of the patterned first and second conductor portions has a space to which an adhesive is applied.

13. A method of fabricating a stacked semiconductor package by s tacking at least two semiconductor chips one above another as a unit, comprising the step of:
printing patterned conductor portions on either of facing surfaces of first and second semiconductor chips to be stacked,
wherein the patterned conductor portions extend from a predetermined lead of the first semiconductor chip to another predetermined lead of the first semiconductor chip or from a predetermined lead of the second semiconductor chip to another predetermined lead of the second semiconductor chip, said predetermined leads of each semiconductor chip being required to be electrically connected to each other.

14. The method as claimed in claim 13, wherein the patterned conductor portions are printed by using an electrically conductive ink or adhesive.

15. The method as claimed in claim 13, further comprising the step of bonding the leads of the first and second semiconductor chips to each other by an electrically conductive adhesive or fusion welding after the first and second semiconductor chips are stacked one above another.

16. The method as claimed in claim 15, wherein the patterned conductor portions are constructed by forming etched portions on either of the surfaces of the semiconductor chips and then filling the etched portions with an electrically conductive ink or adhesive.

17. The method as claimed in claim 16, wherein the patterned conductor portions are constructed by forming etched portions on either of the surfaces of the semiconductor chips and then filling the etched portions with an electrically conductive ink or adhesive.

18. A method of fabricating a stacked semiconductor package by stacking at least two semiconductor chips one above another as a unit, comprising the steps of:
printing first patterned conductor portions extending from a predetermined lead of a first semiconductor chip to a region on a surface of the first semiconductor chip; and
printing second patterned conductor portions extending from a predetermined lead of a second semiconductor chip to a region on a surface of the second semiconductor chip,
wherein the first patterned conductor portions are electrically connected to the second patterned conductor portions when the first and second semiconductor chips are stacked one above another.

19. The method as claimed in claim 18, wherein the first and second patterned conductor portions are printed by using an electrically conductive ink or adhesive.

20. The method as claimed in claim 18, further comprising the step of bonding the leads of the first and second semiconductor chips to each other by an electrically conductive adhesive or fusion welding after the first and second semiconductor chips are stacked one above another.

21. The method as claimed in claim 19, wherein the first and second patterned conductor portions are constructed by forming etched portions on the surfaces of the semiconductor chips and then filling the etched portions with an electrically conductive ink or adhesive.

22. The method as claimed in claim 20, wherein the first and second patterned conductor portions are constructed by forming etched portions on the surfaces of the semiconductor chips and then filling the etched portions with an electrically conductive ink or adhesive.

23. The method as claimed in claim 19, wherein either of the patterned first and second conductor portions has a space to which an adhesive is applied.

24. The method as claimed in claim 20, wherein either of the patterned first and second conductor portions has a space to which an adhesive is applied.
